(19) United States
(12) Patent Application Publication
(10) Pub. No.: US 2026/0293571 A1
(43) Pub. Date: Sep. 24, 2026

(54) CLEANING APPARATUS AND CLEANING METHOD

(71) Applicant: SCREEN Holdings Co., Ltd., Kyoto (JP)

(72) Inventors: Joichi NISHIMURA, Kyoto-shi (JP); Akihiro TAGUMA, Kyoto-shi (JP)

(21) Appl. No.: 19/545,451

(22) Filed: Feb. 20, 2026

(30) Foreign Application Priority Data
Mar. 21, 2025 (JP) 2025-046669

(51) Int. Cl. H10P 72/00; B08B 9/00

(52) U.S. Cl. CPC H10P 72/0414; B08B 9/00

(57) ABSTRACT

This invention relates to a cleaning apparatus for cleaning a work including a plurality of chips arrayed on a surface of a sheet-like carrier with gap formed therebetween. The cleaning apparatus includes: a holder which holds the work in a horizontal posture; a nozzle which is arranged above the work and discharges a cleaning liquid toward the work; and a moving mechanism which moves the nozzle and the holder relative to each other along an extension direction of a groove formed in the gap between the chips. Thus, the work can be effectively cleaned.

### CROSS REFERENCE TO RELATED APPLICATION

The disclosure of Japanese Patent Application No.2025-046669 filed on Mar 21, 2025 including specification, drawings and claims is incorporated herein by reference in its entirety.

### Background of the Invention

### Field of the Invention

This invention relates to a technique for cleaning a work in which diced semiconductor chips, for example, are carried on a sheet-like carrier.

### Description of the Related Art

A semiconductor device manufacturing process includes a dicing step of dicing individual chips (dice) from a semiconductor wafer formed with a plurality of devices. Separation between the chips is performed by adhering the wafer to a stretchable sheet-like carrier and stretching the carrier to form gaps between the chips (expand processing). Since particles such as shavings may enter the gaps (grooves) formed in this way, cleaning is necessary.

For example, in a technique described in JP 2023-178867A (patent literature 1), a work is cleaned by a so-called spin cleaning method. In this method, a cleaning liquid is supplied to the upper surface of the work while the work held in a horizontal posture is rotated, and cleaning is performed by spreading the cleaning liquid to the entire work by a centrifugal force.

Since chips are generally laid out in a two-dimensional matrix on a wafer, grooves separating between the chips in a work are, for example, arranged in a two-dimensional lattice. On the other hand, in spin cleaning, a cleaning liquid supplied to the work radially flows from a center of rotation toward a peripheral edge by a centrifugal force. Thus, a sweeping action by the cleaning liquid does not necessarily sufficiently function for particles adhering to the insides of the grooves. Therefore, the spin cleaning in the above conventional technique has a problem that particles may remain inside the grooves and there is a room for improvement in more effectively performing cleaning.

### SUMMARY OF THE INVENTION

This invention was developed in view of the above problem and proposes a technique capable of effectively cleaning a work structured such that a plurality of chips are arrayed on a carrier while being spaced apart.

One aspect of the invention is directed to a cleaning apparatus for cleaning a work including a plurality of chips arrayed on a surface of a sheet-like carrier with gaps formed therebetween, the cleaning apparatus including a holder for holding the work in a horizontal posture, a nozzle arranged above the work, the nozzle discharging a cleaning liquid toward the work, and a moving mechanism for relatively moving the nozzle and the holder along an extension direction of grooves formed in the gaps between the chips.

Further, another aspect of the invention is directed to a cleaning method for cleaning a work including a plurality of chips arrayed on a surface of a sheet-like carrier with gaps formed therebetween, the cleaning method including holding the work in a horizontal posture, discharging a cleaning liquid from a nozzle arranged above the work toward the work, and relatively moving the nozzle and the work along an extension direction of grooves formed in the gaps between the chips.

In the invention thus configured, a supply position of the cleaning liquid from the nozzle to the work changes with time along the extension direction of the grooves formed in the gaps between the chips by relative movements of the nozzle and the work. Thus, particles adhering to the grooves are efficiently ejected to outside together with the cleaning liquid flowing along the grooves. As a result, in the invention, the work structured such that the plurality of chips are arrayed on the carrier with the gaps formed therebetween can be effectively cleaned.

As described above, according to the invention, the supply position of the cleaning liquid can be changed with time along the direction of the grooves formed between the chips arranged in the work while being spaced apart. Thus, the remaining of the particles in the grooves can be suppressed and the work can be effectively cleaned.

The above and further objects and novel features of the invention will more fully appear from the following detailed description when the same is read in connection with the accompanying drawing. It is to be expressly understood, however, that the drawing is for purpose of illustration only and is not intended as a definition of the limits of the invention.

### BRIEF DESCRIPTION OF THE DRAWINGS

FIGS. 1A to 1C are diagrams schematically showing a configuration example of a work;

FIGS. 2A to 2C are diagrams schematically showing a specific mode of the cleaning process;

FIGS. 3A and 3B are diagrams showing a first embodiment of the cleaning apparatus;

FIG. 4 is a flow chart showing the cleaning process in the first embodiment;

FIG. 5 is a top view showing the second embodiment of the cleaning apparatus;

FIG. 6 is a top view showing the third embodiment of the cleaning apparatus;

FIGS. 7A and 7B are diagrams showing a fourth embodiment of the cleaning apparatus; and

FIG. 8 is a flow chart showing a cleaning process in this embodiment.

### DETAILED DESCRIPTION OF THE PREFERRED EMBODIMENTS

Hereinafter, several embodiments of a cleaning apparatus according to the invention are described. A work to be cleaned by these embodiments is common and the principle of a cleaning process is also common. Accordingly, the work to be cleaned and the principle of the cleaning process are first described.

### Description of Work

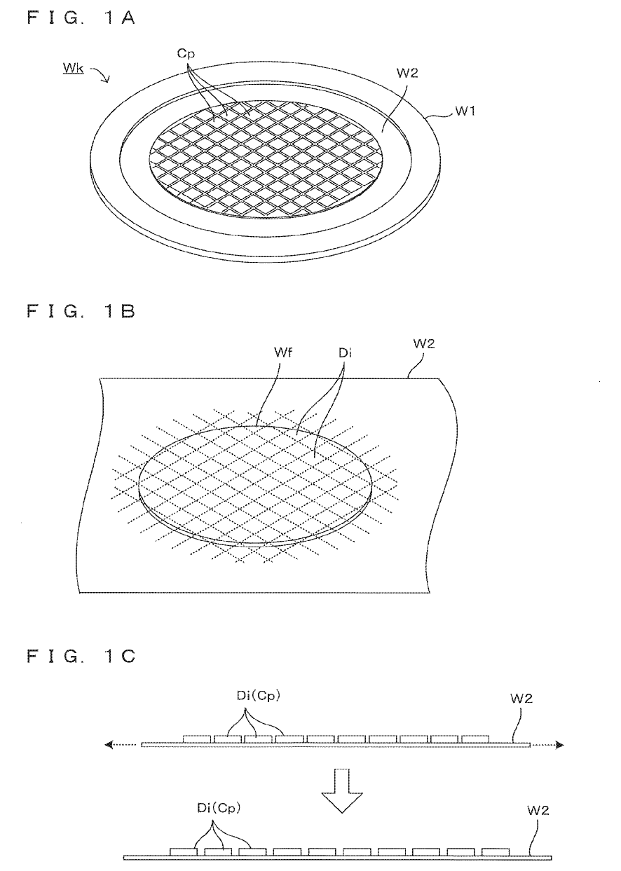

FIGS. 1A to 1C are diagrams schematically showing a configuration example of a work. More specifically, FIG. 1A is a diagram showing the external appearance of a work Wk, and FIG. 1B is a diagram schematically showing a dicing processing for a semiconductor wafer (hereinafter, a “wafer”) Wf. Further, FIG. 1C is a diagram schematically showing an expand processing for the diced wafer Wf.

As shown in FIG. 1A, the work Wk to be processed in each of embodiments to be described later is configured such that a plurality of chips Cp diced from the wafer Wf are arrayed in a two-dimensional matrix on the upper surface of a sheet-like dicing tape W2 stretched in a hollow part of a flat ring-like dicing frame W1. Each chip Cp finally becomes a semiconductor device such as an integrated circuit.

Since the dicing processing of dicing the plurality of chips Cp collectively formed in the wafer Wf from the wafer Wf is known, it is briefly described here. As shown in FIG. 1B, the substantially disk-like wafer Wf is divided into a plurality of dice Di along cutting lines shown by dotting lines, for example, by a cutting means such as a diamond blade or a laser cutter.

At this time, to prevent the separated dice Di from scattering, the wafer Wf is mounted on the dicing tape W2. That is, the dicing tape W2 is adhered to the underside of the wafer Wf in advance. The dicing tape W2 is a stretchable sheet-like material, for example, made of resin, and adheres to and holds the wafer Wf by an adhesive applied to a surface. The dicing tape is also called a DAF (Die Attach Film).

After wafer cutting, the dicing tape W2 is stretched outward in surface directions (expand processing) as shown in FIG. 1C. By doing so, intervals between the separated dice Di expand. As a result, each die Di (chip Cp) is easily removed from the dicing tape W2. Note that, here, small pieces separated from the wafer Wf are called the dice Di and, out of those, one formed with a circuit or the like and planned to function as a semiconductor device is called the chip Cp.

Since the dicing tape W2 is a flexible material, a peripheral edge part is fixed by the ring-shaped dicing frame W1 for easy handling. In this way, the work Wk is configured. Note that the work Wk to be cleaned may be either such that the intervals between the chips Cp after dicing and before expansion are relatively narrow or such that the intervals between the chips Cp after expansion are wide.

### Principle of Cleaning Process

In the work Wk configured as described above, the chips Cp are arrayed in a two-dimensional matrix and gaps are provided between the respective chips Cp. Thus, grooves are formed between adjacent ones of the chips Cp. When the respective chips Cp have a rectangular shape and are linearly arrayed, a chip array direction and an extension direction of the grooves formed between those chips intersect each other. On the other hand, if the chips Cp are two-dimensionally arrayed in two array directions, the grooves extending along each of those array directions are formed into a lattice.

Particles such as shavings produced by dicing enter these grooves, and a cleaning process for removing these is necessary. Here, in spin cleaning for supplying a cleaning liquid while rotating a work as in the conventional technique, a flow of the cleaning liquid radially occurring by a centrifugal force and the extension directions of the grooves between the chips do not necessarily coincide. Thus, side surfaces of the chips Cp serve as barriers and the ejection of the particles does not proceed, with the result that the particles remain in the grooves. This hinders an improvement in cleaning efficiency.

In view of this problem, in each embodiment to be described later, a nozzle for discharging the cleaning liquid and the work Wk are relatively moved along the extension direction of the grooves. In this way, the flow of the cleaning liquid along the grooves is generated and the ejection of the particles remaining in and adhering to the insides of the grooves is promoted and a cleaning effect can be enhanced.

Note that the dicing frame W1, the dicing tape W2 and the dice Di (chips Cp) are integrated in the work Wk as described above, but, out of these, the dicing frame W1 and the dicing tape W2 are auxiliary tools for maintaining the postures of the dice Di. From this, in the following description, the work Wk may be shown as an aggregate of the dice Di (chips Cp) without the dicing frame W1 and the dicing tape W2.

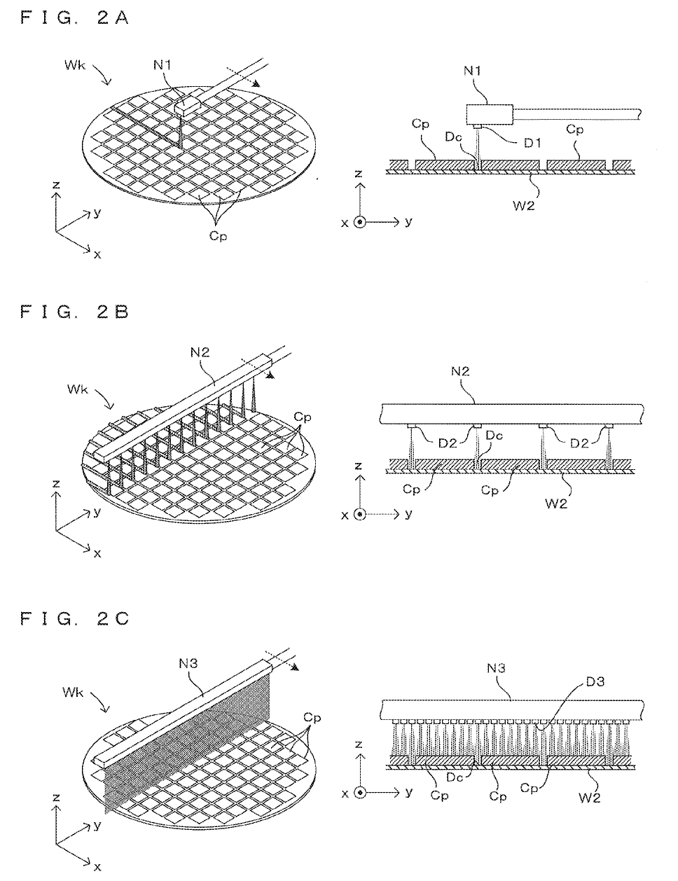

FIGS. 2A to 2C are diagrams schematically showing a specific mode of the cleaning process. Here, to uniformly show directions, in the work Wk having the rectangular chips Cp two-dimensionally arrayed, an orthogonal coordinate system is so set that one array direction of the chips Cp is set as an x direction, another array direction orthogonal to the one array direction is set as a y direction, and a direction perpendicular to a principle surface of the work Wk is set as a z direction. Further, in each of FIGS. 2A to 2C, a left view is a perspective view showing a cleaning mode and a right view is a partial side sectional view of the cleaning mode.

In an example shown in FIG. 2A, a nozzle N1 including one discharge port D1 is arranged above the work Wk. The nozzle N1 is positioned to be located right above one groove Dc formed in the work Wk and extending in the x direction, and scanned and moved in the x direction as indicated by a dotted-line arrow while discharging the cleaning liquid toward the groove Dc from the discharge port D1. In this way, in the groove Dc to which the cleaning liquid is supplied, particles are swept away in the x direction by the cleaning liquid and finally removed from the work Wk. A discharge mode of the cleaning liquid may be any one of spraying, continuous flowing-down and intermittent dripping.

If scanning is finished for one groove Dc, the position of the nozzle N1 is successively moved in the y direction. In this way, for another groove, the discharge port D1 is positioned right above this groove and the cleaning liquid is discharged, whereby this groove can be effectively cleaned. As just described, in the first example shown in FIG. 2A, the nozzle N1 including the single discharge port D1 is used and each groove formed in the work Wk is cleaned by scanning and moving the nozzle N1 in the x direction and the y direction.

In a second example shown in FIG. 2B, a nozzle N2 provided with a plurality of discharge ports D2 at the same array pitches as the chips Cp in the work Wk is used. The nozzle N2 is scanned and moved in the x direction with the respective discharge ports D2 positioned in the y direction to be at the same positions as the respective grooves Dc of the work Wk. In this case, the plurality of grooves Dc respectively extending in the x direction and arranged side by side in the y direction are simultaneously cleaned by the cleaning liquid discharged from the nozzle N2. Therefore, the work Wk can be cleaned in a shorter time than in the first example.

In a third example shown in FIG. 2C, a nozzle N3 provided with a plurality of discharge ports D3 at finer array pitches than those of the chips Cp in the work Wk is used. Thus, the cleaning liquid is supplied to the work Wk like a curtain having a longitudinal direction in the y direction. In this state, the nozzle N3 is scanned in the x direction. In this way, not only the grooves Dc, but also the surfaces of the chips Cp can be cleaned by the cleaning liquid. Further, since the discharge ports of the nozzle need not be aligned with the array pitches of the chips Cp, works having different chip sizes can also be dealt with.

As described above, a basic way of thinking of cleaning for the work Wk is such that the ejection of the particles in the grooves Dc is promoted by scanning and moving the nozzle for discharging the cleaning liquid along the extension directions of the grooves Dc formed in the work Wk. By doing so, the grooves Dc can be effectively cleaned. In the third example shown in FIG. 2C, the surfaces of the chips Cp can be further simultaneously cleaned.

In the above description of the principle, only the cleaning of the grooves extending in the x direction is mentioned, but the grooves extending in the y direction can be similarly cleaned. That is, the grooves can be cleaned by moving the nozzle in the y direction while supplying the cleaning liquid from the nozzle to the grooves extending in the y direction. Further, although the examples of moving the nozzle with respect to the work have been described here, it is sufficient to realize relative movements of the work and the nozzle. Therefore, the nozzle may be fixed and the work may be moved. Further, as long as relative movements along the grooves are realized, the movement of the work and the movement of the nozzle may be combined.

Hereinafer, several specific embodiments of the cleaning apparatus according to the invention configured based on the above principle are described in detail. Note that components common among the respective embodiments are denoted by common reference signs and the description of those is not repeated unless it is particularly necessary.

### First Embodiment

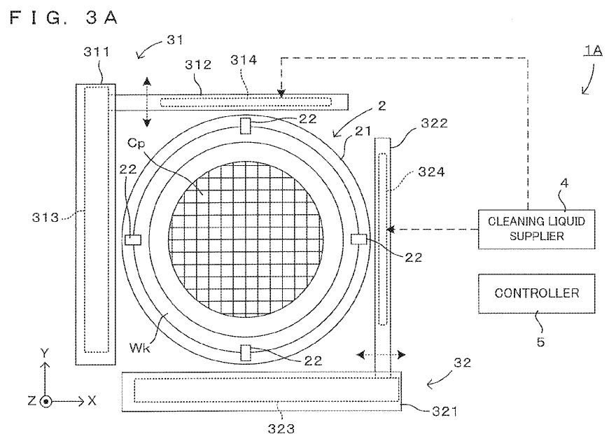

FIGS. 3A and 3B are diagrams showing a first embodiment of the cleaning apparatus according to the invention. More specifically, FIG. 3A is a top view of a cleaning apparatus 1A according to the first embodiment and FIG. 3B is a side view thereof. Note that, in FIG. 3B, the dicing frame W1 of the work Wk is shown by a cross-section thereof to make a device configuration easily understandable.

In FIG. 3A and subsequent figures, an XYZ orthogonal coordinate system is introduced to show directions in the device. This is a coordinate system defined in a real space and having an XY plane as a horizontal plane and a Z axis as a vertical axis, unlike the xyz coordinate system, which is a local coordinate system used to show the array directions of the chips Cp in FIG. 2 and the like.

The cleaning apparatus 1A is provided with a holder 2, a first cleaner 31, a second cleaner 32, a cleaning liquid supplier 4 and a controller 5 as main components. The holder 2 holds the work Wk in a substantially horizontal posture. The first cleaner 31 and the second cleaner 32 respectively discharge the cleaning liquid toward the work Wk. The cleaning liquid supplier 4 supplies the cleaning liquid to the first and second cleaners 31, 32.

The controller 5 realizes a desired operation by controlling each component of the device in accordance with a control program prepared in advance. For this purpose, the controller 5 is provided with unillustrated CPU, memory, storage, interface and the like. That is, in the controller 5, the CPU executes the control program stored in the storage and realizes the cleaning process by controlling the operation of each component of the device.

The holder 2 holds the work in a horizontal posture or a substantially horizontal posture. For this purpose, the holder 2 is provided with a work base 21 having a plane size one size larger than the external size of the work Wk and having the work Wk placed thereon, chuck mechanisms 22 for fixing the work Wk, and an elevating mechanism 23 for supporting the work base 21 and elevating and lowering the work base 21 in the Z direction. A plurality of the chuck mechanisms 22 are provided at substantially equal angular intervals on the upper surface of the work base 21. The chuck mechanism 22 switches a state between a holding state for fixing the work Wk placed on the work base 21 and a releasing state for releasing the fixed state in response to a control command from the controller 5. The elevating mechanism 23 adjusts a distance between the work Wk and a nozzle to be described later by elevating and lowering the work base 21.

The first cleaner 31 is provided with a base 311 arranged adjacent to the holder 2 on a (-X) side and a nozzle arm 312 horizontally extending in a (+X) direction from above the base 311. A moving mechanism 313 for horizontally moving the nozzle arm 312 in the Y direction as indicated by dotted-line arrows in response to a control command from the controller 5 is built in the base 311. Various actuators can be applied as the moving mechanism 313 for realizing such linear motions. For example, a linear motor, a ball screw mechanism, a linear motion guide, a single axis robot or the like can be applied as the moving mechanism 313.

The nozzle arm 312 extends in the X direction above the work Wk held by the holder 2, and a nozzle 314 is provided on the lower surface thereof. Array pitches of discharge ports provided in the nozzle 314 are the same as the array pitches of the chips Cp in the work Wk as shown in FIG. 2B or smaller than the array pitches of the chips Cp in the work Wk as shown in FIG. 2C. A length in the X direction of the nozzle 314 is set to cover an entire distribution range in the X direction of the chips Cp arranged in the work Wk.

The cleaning liquid is supplied to the nozzle 314 from the cleaning liquid supplier 4. A composition of the cleaning liquid is not particularly limited, but pure water or de-ionized water (DIW) can be, for example, used. A pipe for feeding the cleaning liquid is preferably flexible to follow a movement of the nozzle arm 312.

The second cleaner 32 also has a structure similar to that of the first cleaner 31. That is, the second cleaner 32 is provided with a base 321 arranged adjacent to the holder 2 on a (-Y) side and a nozzle arm 322 horizontally extending in a (+Y) direction from above the base 321. A moving mechanism 323 for horizontally moving the nozzle arm 322 in the X direction as indicated by dotted-line arrows in response to a control command from the controller 5 is built in the base 321. Note that the cleaner 32 is not shown in FIG. 3B.

The nozzle arm 322 extends in the Y direction above the work Wk held by the holder 2, and a nozzle 324 is provided on the lower surface thereof. Array pitches of discharge ports provided in the nozzle 324 are the same as the array pitches of the chips Cp in the work Wk as shown in FIG. 2B or smaller than the array pitches of the chips Cp in the work Wk as shown in FIG. 2C. A length in the Y direction of the nozzle 324 is set to cover an entire distribution range in the Y direction of the chips Cp arranged in the work Wk. The cleaning liquid is supplied to the nozzle 324 from the cleaning liquid supplier 4.

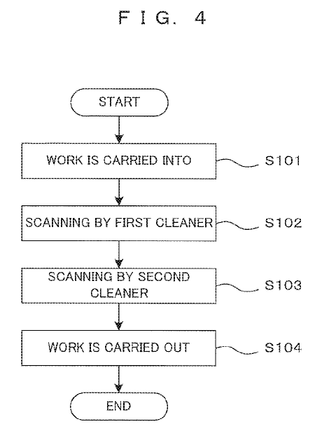

FIG. 4 is a flow chart showing the cleaning process in the first embodiment. The work Wk to be cleaned after the dicing processing or after the expand processing is carried into the cleaning apparatus 1A by an external conveyor device (Step S101). The work Wk is placed in a horizontal posture on the work base 21 and fixed by the chuck mechanisms 22. At this time, the work Wk is so placed that the xy directions, in which the grooves extend in the work Wk, and the XY directions defined in the cleaning apparatus 1A coincide.

Subsequently, scanning by the first cleaner 31 is performed (Step S102). Specifically, the moving mechanism 313 moves the nozzle arm 312 in the Y direction with the nozzle 314 of the first cleaner 31 discharging the cleaning liquid supplied from the cleaning liquid supplier 4. Thus, the Wk is scanned by the cleaning liquid. In this way, the grooves extending in the Y direction, out of the work Wk, are cleaned.

Thereafter, scanning by the second cleaner 32 is performed (Step S103). That is, the moving mechanism 323 moves the nozzle arm 322 in the X direction with the nozzle 324 of the second cleaner 32 discharging the cleaning liquid supplied from the cleaning liquid supplier 4. In this way, the work Wk is scanned by the cleaning liquid and the grooves extending in the X direction, out of the work Wk, are cleaned. In this way, the grooves in the both X and Y directions are cleaned.

Steps S102 and S103 may be repeated a plurality of times if necessary. After the discharge and scanning of the cleaning liquid are stopped, the work Wk is carried out (Step S104) and a series of processings are finished. This operation is basically the same also in second and third embodiments to be described later.

As just described, the cleaning apparatus 1A of this embodiment is provided with the first cleaner 31 for scanning the grooves extending in the Y direction, out of the work Wk, and the second cleaner 32 for scanning the grooves extending in the X direction. The first cleaner 31 collectively scans all the grooves extending in the Y direction by the cleaning liquid, whereas the second cleaner 32 collectively scans all the grooves extending in the X direction by the cleaning liquid. Therefore, by combining scanning by the first cleaner 31 and scanning by the second cleaner 32, all the grooves to be cleaned in the work Wk can be cleaned.

In principle, the entire work Wk can be effectively cleaned in a short time by one scanning by the first cleaner 31 and one scanning by the second cleaner 32. Further, when the nozzles 314, 324 used have the structure shown in FIG. 2C, not only the grooves between the chips Cp, but also the surfaces of the chips Cp can be simultaneously cleaned. Further, when the nozzles 314, 324 have the structure shown in FIG. 2B, if the array pitches of the chips Cp in the work Wk are changed, nozzles including discharge ports having array pitches corresponding to the changed array pitches need to be prepared. On the other hand, when the nozzles 314, 324 have the structure shown in FIG. 2C, it is not necessary to change the nozzle in accordance with the array pitches of the chips Cp.

### Second Embodiment

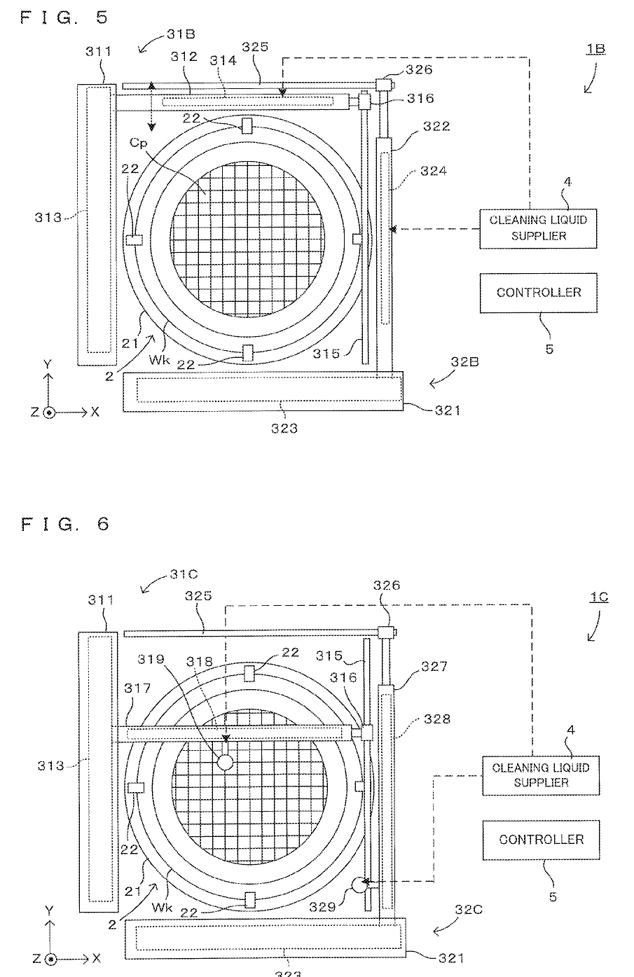

FIG. 5 is a top view showing the second embodiment of the cleaning apparatus according to the invention. A cleaning apparatus 1B of the second embodiment differs from the cleaning apparatus 1A of the first embodiment in that the tips of nozzle arms 312, 322 are engaged with guide rails. Since there is no difference between the first and second embodiments except this point, common components are denoted by common reference signs and the configurations and operations thereof are not described as described above.

In a first cleaner 31B of this embodiment, a guide rail 315 extending in the Y direction is provided on a (+X) side of a holder 2. A slider 316 mounted on a tip side on the (+X) side of the nozzle arm 312 is engaged with the guide rail 315 movably in the Y direction. Similarly, in the second cleaner 31B, a guide rail 325 extending in the X direction is provided on a (+Y) side of the holder 2. A slider 326 mounted on a tip side on the (+Y) side of the nozzle arm 322 is engaged with the guide rail 325 movably in the X direction.

If the nozzle arms 312, 322 are cantilevered as in the first embodiment, a cleaning liquid supply position may possibly become unstable due to the hanging down of the nozzle tips by their own weights or the shake during a movement, depending on their structures. By engaging the arm tips with the guide rails as in this embodiment, this problem is solved.

### Third Embodiment

FIG. 6 is a top view showing the third embodiment of the cleaning apparatus according to the invention. In this embodiment, the structures of nozzle arms and nozzles are different from those of the first and second embodiments. Note that the embodiment based on a structure including guide rails similarly to the second embodiment is shown here, but this embodiment can be also based on the structure of the first embodiment provided with no guide rails.

The example shown in FIG. 2A is applied as the principle of the cleaning process to a cleaning apparatus 1C of this embodiment. That is, in the cleaning apparatus 1C, a nozzle arm 317 of a first cleaner 31C includes a nozzle moving mechanism 318, and a nozzle 319 is attached to the nozzle moving mechanism 318. An appropriate linear motion mechanism, e.g. a linear motor, a ball screw mechanism, a linear motion guide, a single axis robot or the like is suitably applicable as the nozzle moving mechanism 318. The nozzle 319 includes a single discharge port, and a cleaning liquid supplied from a cleaning liquid supplier 4 is discharged.

Similarly, in a second cleaner 32C, a nozzle arm 327 includes a nozzle moving mechanism 328, and a nozzle 329 is attached to the nozzle moving mechanism 328. The nozzle 329 includes a single discharge port, and the cleaning liquid supplied from the cleaning liquid supplier 4 is discharged.

According to such a configuration, scanning in the Y direction by the first cleaner 31C and scanning in the X direction by the second cleaner 32 clean one groove in each scan. Accordingly, all the grooves may be cleaned as follows. That is, in the first cleaner 31C, a scanning movement in the Y direction by the moving mechanism 313 is a main scanning movement, and a sub scanning movement of the nozzle 319 is made in the X direction by the array pitch of the chips Cp by the nozzle moving mechanism 318 every time one main scanning movement is finished. In this way, all the grooves extending in the Y direction can be cleaned.

Similarly, in the second cleaner 32C, a scanning movement in the X direction by the moving mechanism 323 is a main scanning movement, and a sub scanning movement of the nozzle 329 is made in the Y direction by the array pitch of the chips Cp by the nozzle moving mechanism 328 every time one main scanning movement is finished. In this way, all the grooves extending in the X direction can be cleaned.

In this embodiment, a feed pitch of the nozzle position in the sub scanning movement can be arbitrarily set by a control of a controller 5. Thus, various works Wk having different chip sizes and array pitches can be dealt with, and the nozzle needs not be changed every time the type of the work Wk is changed.

Note that, although each of the first and second cleaners 31C, 32C used includes the single discharge port here, either of these cleaners may have the structure shown in the first or second embodiment.

### Fourth Embodiment

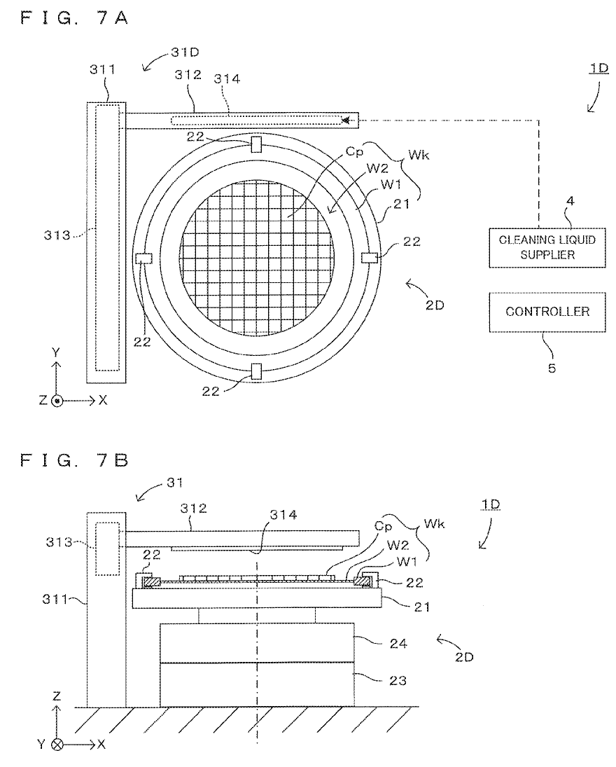

FIGS. 7A and 7B are diagrams showing a fourth embodiment of the cleaning apparatus according to the invention. More specifically, FIG. 7A is a top view of a cleaning apparatus 1D according to the fourth embodiment and FIG. 7B is a side view thereof. As shown in FIG. 7A, a second cleaner is omitted in the cleaning apparatus 1D of this embodiment. The structure of a first cleaner 31D is the same as the first cleaner 31 of the first embodiment. Therefore, a work Wk can be scanned only in the Y direction. Thus, only grooves extending in the y direction are cleaned in the work Wk.

The grooves extending in the x direction are cleaned by rotating the work Wk by 90° about a vertical axis. That is, in a holder 2D of this embodiment, a rotating mechanism 24 is provided between an elevating mechanism 23 and a work base 21. The rotating mechanism 24 rotates the work base 21 by 90° about the vertical axis shown by a one-dot chain line in FIG. 7B. Various actuators are applicable as such a rotating mechanism 24. For example, the rotating mechanism 24 may be composed of a rotary shaft and a motor for rotating the rotary shaft. In this way, a switch is made between a state where the X direction in the real space and the x direction in the work Wk coincide and a state where the X direction in the real space and the y direction in the work Wk coincide.

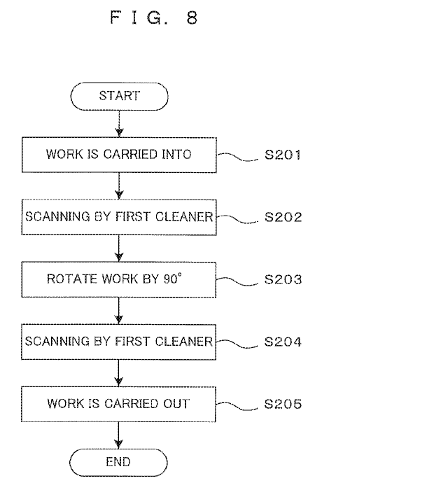

FIG. 8 is a flow chart showing a cleaning process in this embodiment. The cleaning process is the same as that of the first embodiment in that the work Wk is carried into with the x direction coinciding with the X direction in the real space (Step S201) and scanned in the Y direction by the first cleaner 31D (Step S202). In this way, grooves in the y direction in the work Wk are cleaned.

Subsequently, the rotating mechanism 24 rotates the work base 21 by 90° (Step S203). In this way, the x direction of the work Wk coincides with the Y direction in the real space. In this state, scanning in the Y direction, i.e., along the x direction of the work Wk, is performed again by the first cleaner 31D (Step S204). In this way, the grooves extending in the x direction are also cleaned. Thereafter, the work Wk is carried out and the process is finished as in the first embodiment (Step S205). Note that a step may be provided in which the work base 21 is returned to an original position by being rotated by 90° in a reverse direction by the rotating mechanism 24 before the work is carried out.

In this embodiment, by not providing the second cleaner, a mechanism for rotating the work base 21 is added while a device configuration is simplified particularly in relation to a cleaning liquid supply system. Which merit is larger depends on a situation, but a footprint of the device can be made smaller in this embodiment than in the other embodiments. Note that a nozzle arm 312 is not supported by a guide rail here, but may be supported by a guide rail as in a first cleaner 31B shown in FIG. 5.

### Miscellaneous

As described above, in each of the above embodiments, the cleaning apparatus 1A to 1D corresponds to a “cleaning apparatus” of the invention. The holder 2, the nozzle 314, 324, the moving mechanism 313 and the like respectively function as a “holder”, a “nozzle” and a “moving mechanism” of the invention. Further, the x direction and the y direction correspond to “array directions” of the invention. If the Y direction and the X direction are respectively viewed as a “first direction” and a “second direction” of the invention, the nozzle 314, 319 corresponds to a “first nozzle” of the invention, whereas the nozzle 324, 329 corresponds to a “second nozzle” of the invention. The rotating mechanism 24 functions as a “rotating mechanism” of the invention. Further, the dicing tape W2 corresponds to a “carrier” of the invention.

Note that the invention is not limited to the embodiments described above, and various changes can be made besides the aforementioned ones without departing from the gist of the invention. For example, although the dicing frame W1 is assumed to have a circular ring shape and the work base 21 is assumed to have a circular plate shape for the description of the principle in the description of each of the above embodiments, a dicing frame used in an actual manufacturing site has a more complicated shape as also disclosed in patent literature 1. Therefore, the shape of a work base can be appropriately changed according to the shape and structure of a dicing frame.

Particularly, if the shape of the dicing frame is rotationally asymmetric, the “coincidence of the xy directions and the XY directions” in the above embodiments can be easily and reliably realized, utilizing that shape feature.

Further, in the above embodiments, the nozzle 314 or the like moves with respect to the fixed work Wk, whereby relative movements of the both are realized. However, a work may be, for example, moved with respect to a fixed nozzle. For example, in the case of processing a plurality of works, if the plurality of works successively pass a position right below the fixed nozzle, those works can be efficiently cleaned.

Further, for example, in the above embodiments, the fixing of the work Wk to the work base 21 is realized by the chuck mechanisms 22 for mechanically pressing the work Wk. However, a holding mode of the work Wk is arbitrary without being limited to this. For example, the work Wk can be held by providing a suction hole, to which a negative pressure is applied, in the upper surface of the work base and vacuum-suctioning the lower surface of the dicing frame W1 of the work Wk.

Further, for example, the cleaning process is performed using only one type of the cleaning liquid in the above embodiments, but a plurality of cleaning liquids such as a chemical solution and a rinse liquid may be, for example, used. In this case, after one groove or the work is entirely processed by one cleaning liquid, cleaning by another cleaning liquid may be performed. Further, cleaning by the plurality of cleaning liquids may be realized by one relative movement by arranging a plurality of nozzles along a relative moving direction and discharging different cleaning liquids from the nozzles.

As the specific embodiments have been illustrated and described above, the nozzle may be configured to discharge the cleaning liquid toward the groove from a discharge port provided at a position above the groove in a cleaning apparatus according to the invention. According to this configuration, since the discharged cleaning liquid can be directly guided to the groove, the groove can be effectively cleaned.

In this case, for example, the moving mechanism can position the discharge port to each of a plurality of grooves in turn by relatively moving the nozzle and the holder along an array direction every time the discharge port is positioned to one of the grooves. By doing so, the plurality of grooves can be successively cleaned. If array pitches of chips are changed, this can be dealt with by changing a feed pitch in the array direction.

Alternatively, for example, the nozzle may be provided with a plurality of the discharge ports respectively corresponding to a plurality of grooves. According to such a configuration, a plurality of grooves can be cleaned by one relative movement and a processing time can be shortened.

Further, for example, the nozzle may be provided with a plurality of the discharge ports at smaller pitches than array pitches of grooves along an array direction of the chips. According to such a configuration, the cleaning liquid can be supplied to between grooves, i.e. to surfaces of chips arrayed in a work. Therefore, the chip surfaces and the grooves around the chips can be simultaneously cleaned. That is, an effect of cleaning the surfaces of the chips can be obtained in addition to an effect of cleaning the grooves.

Further, if a plurality of chips are two-dimensionally arrayed in two array directions intersecting each other in the work to be processed, the moving mechanism may be configured to relatively move the nozzle and the holder along each of the two array directions. In such a work including the two-dimensionally arrayed chips, grooves in two directions along the two array directions are formed. By relatively moving the nozzle and the holder in each of the two array directions, the both grooves of these two types can be cleaned.

In this case, a first nozzle configured to move in a first direction, out of the two array directions, and a second nozzle configured to move in a second direction different from the first direction, out of the two array directions, may be provided for relative movements with respect to the holder by the moving mechanism. That is, dedicated nozzles may be respectively provided to correspond to the grooves of two types extending in different directions and intersecting each other. These nozzles respectively relatively move with respect to the work, whereby the grooves having different extension directions can be efficiently cleaned.

Alternatively, a rotating mechanism for rotating a holder about a vertical axis may be provided, and relative movements of the nozzle and the holder by a moving mechanism along each of two array directions may be realized by the rotating mechanism changing an angle of rotation of the holder. According to such a configuration, the grooves of two types having different extension directions can be both cleaned, using the same nozzle. Thus, the device configuration can be made contact.

This invention is applicable to processes in general including a dicing step of separating a semiconductor wafer in units of chips, and particularly suitable for the purpose of cleaning a diced work.

Although the invention has been described with reference to specific embodiments, this description is not meant to be construed in a limiting sense. Various modifications of the disclosed embodiment, as well as other embodiments of the present invention, will become apparent to persons skilled in the art upon reference to the description of the invention. It is therefore contemplated that the appended claims will cover any such modifications or embodiments as fall within the true scope of the invention.

What is claimed is:

1. A cleaning apparatus to clean a work including a plurality of chips arrayed on a surface of a sheet-like carrier with gap formed therebetween, the cleaning apparatus comprising:
a holder which holds the work in a horizontal posture;
a nozzle which is arranged above the work and discharges a cleaning liquid toward the work; and
a moving mechanism which moves the nozzle and the holder relative to each other along an extension direction of a groove formed in the gap between the chips.

2. The cleaning apparatus according to claim 1, wherein the nozzle discharges the cleaning liquid toward the groove from a discharge port provided at a position above the groove.

3. The cleaning apparatus according to claim 2, wherein:
the moving mechanism moves the nozzle and the holder relatively along an array direction of the chips, thereby positions the discharge port to each of a plurality of the grooves in turn; and
the moving mechanism moves the nozzle and the holder relatively along the extension direction every time the discharge port is positioned to one of the grooves.

4. The cleaning apparatus according to claim 2, wherein the nozzle is provided with a plurality of the discharge ports respectively corresponding to a plurality of the grooves.

5. The cleaning apparatus according to claim 2, wherein the nozzle is provided with a plurality of the discharge ports at smaller pitches than array pitches of the grooves along an array direction of the chips.

6. The cleaning apparatus according to claim 1 to clean the work in which a plurality of chips are two-dimensionally arrayed in two array directions intersecting each other, wherein
the moving mechanism moves the nozzle and the holder relatively along each of the two array directions.

7. The cleaning apparatus according to claim 6, further comprising a first nozzle and a second nozzle as the nozzle, wherein in moving relative to the holder by the moving mechanism,
the first nozzle moving in a first direction out of the two array direction, and the second nozzle moving in a second direction different from the first direction, out of the two array direction.

8. The cleaning apparatus according to claim 6, further comprising a rotating mechanism which rotates the holder about a vertical axis, wherein relative movements of the nozzle and the holder by the moving mechanism along each of the two array directions are realized by changing an angle of rotation of the holder by the rotating mechanism.

9. A cleaning method for cleaning a work including a plurality of chips arrayed on a surface of a sheet-like carrier with gaps formed therebetween, the cleaning method comprising:
holding the work in a horizontal posture;
discharging a cleaning liquid from a nozzle arranged above the work toward the work; and
moving the nozzle and the work relative to each other along an extension direction of grooves formed in the gaps between the chips.
